(19) United States
(12) Patent Application Publication
(10) Pub. No.: US 2026/0206198 A1
(43) Pub. Date: Jul. 16, 2026

(54) CALIBRATING TOOL FOR A SELECTIVE SOLDERING UNIT, SELECTIVE SOLDERING INSTALLATION AND CALIBRATING METHOD

(71) Applicant: HELLA GmbH & Co. KGaA, Lippstadt (DE)

(72) Inventors: Christoffer ZEHNDER, Lippstadt (DE); Alexander HAMMELBECK, Lippstadt (DE)

(73) Assignee: HELLA GmbH & Co. KGaA, Lippstadt (DE)

(21) Appl. No.: 19/462,024

(22) Filed: Jan. 28, 2026

Related U.S. Application Data
(63) Continuation of application No. PCT/EP2024/069602, filed on Jul. 11, 2024.

(30) Foreign Application Priority Data
Jul. 28, 2023 (DE) 10 2023 120 201.4

(51) Int. Cl. H05K 13/08; B23K 1/00; B23K 1/08; B23K 3/08; H05K 3/34; B23K 101/42

(52) U.S. Cl. CPC H05K 13/089; B23K 1/0016; B23K 1/085; B23K 3/08; H05K 3/34; B23K 2101/42; H05K 2203/04

(57) ABSTRACT

A calibrating tool for calibrating a selective soldering installation comprising a workpiece-carrier unit, for receiving at least one or more workpieces, and at least one workpiece, such as a circuit board, and at least one measuring unit, wherein the measuring unit is designed as a distance-measuring unit, which can be received within the workpiece-carrier unit and is intended for calibrating a distance of a supporting surface of the workpiece-carrier unit from at least one soldering nozzle of a soldering unit, or as at least one temperature-measuring unit, which can be received within the workpiece-carrier unit and is intended for calibrating at least one heating output of a preheating unit, or as at least one wave-height-measuring unit, which can be received within the workpiece-carrier unit and is intended for calibrating the wave height at least one soldering nozzle of the soldering unit.

This nonprovisional application is a continuation of International Application No. PCT/EP2024/069602, which was filed on July 11, 2024, and which claims priority to German Patent Application No. 10 2023 120 201.4, which was filed in Germany on July 28, 2023, and which are both herein incorporated by reference.

### BACKGROUND OF THE INVENTION

### Field of the Invention

The present invention relates to a calibrating tool for calibrating a selective soldering installation, to a selective soldering installation with a calibrating tool, and to a method for calibrating a selective soldering installation.

### Description of the Background Art

Selective soldering of components, e.g., onto printed circuit boards, is carried out industrially, e.g., using automated selective soldering installations. The circuit boards are first placed in workpiece receiving frames, then preheated to the required temperature, and then the components are selectively soldered in. Recently, a mini-wave soldering process has often been used as a soldering method, in which the liquefied solder is continuously transported to the soldering point by means of a small soldering nozzle in a small and locally limited area of the circuit board. For optimal soldering results, the wave height resulting from the continuous solder flow at the soldering nozzle and a distance between the circuit board and the soldering nozzle must be set precisely to setpoints. Further, the preheating temperature must correspond to the setpoint.

The individual parameters of a selective soldering installation, such as a soldering temperature, a distance of the soldering nozzles from the circuit board, and the wave height of the solder at the soldering nozzle, must be recalibrated for each workpiece. In the state of the art, this is essentially done manually by the user. For this purpose, an empirical value is first assumed for each individual parameter, such as a heating output of a preheating pyrometer. The circuit board is then heated and removed and the preheating temperature of the circuit board is then measured manually. The heating output of the preheating pyrometer is then adjusted and monitored until the desired setpoint is reached. In so doing, adjustment of the parameters, such as the heating output, always occurs based on the experience of the user who calibrates the selective soldering installation. The other parameters as well are calibrated in the same way, so that the calibration of the individual parameters is time-consuming overall. Particularly with small or medium-sized batches, this leads to long downtimes and high personnel costs, which make the selective soldering installation uneconomical to operate.

### SUMMARY OF THE INVENTION

It is therefore an object of the present invention to reduce the downtimes of a selective soldering installation and to increase thereby the economic efficiency of the selective soldering installation.

The object is achieved by a calibrating tool for a selective soldering installation and by a selective soldering installation, as well as by a method for calibrating the selective soldering installation. Advantageous refinements are the subject of the dependent claims.

The calibrating tool in an example of the invention for calibrating a selective soldering installation comprises at least: a workpiece-carrier unit for receiving at least one workpiece; and at least one workpiece such as a circuit board with at least one measuring unit, which is received in particular on the workpiece, wherein the measuring unit is designed as at least one temperature-measuring unit, which can be received within the workpiece-carrier unit and is intended for calibrating at least one heating output of a preheating unit, or as at least one distance-measuring unit, which can be received within the workpiece‑carrier unit and is intended for calibrating a distance of a supporting surface of the workpiece-carrier unit from at least one soldering nozzle of a soldering unit, or as at least one distance-measuring unit, which can be received within the workpiece‑carrier unit and is intended for calibrating the wave height of at least one soldering nozzle of a soldering unit.

The invention has many advantages. A significant advantage of the invention is that the essential parameters of the selective soldering installation can be measured by the calibrating tool and calibrated directly, in particular in situ, i.e., that the individual parameters of the selective soldering installation can be set to setpoints. In this case, rapid calibration is essentially independent of the operator's experience, because the operator always receives rapid feedback when there is a change in the settings. As a result, the downtimes of the selective soldering installation can be advantageously reduced, so that overall a higher economic efficiency of a selective soldering installation is achieved. Advantageously, a calibration can take place using a single calibrating tool by a combination of the temperature-measuring unit, the distance-measuring unit, and/or the wave-height-measuring unit, so that the economic efficiency of the selective soldering installation is increased further.

The workpiece can be designed as a test workpiece, such as a circuit board or a component with a circuit board shape, on which the temperature-measuring unit, the distance-measuring unit, and/or the wave-height-measuring unit are received.

The temperature-measuring unit can comprise a plurality of temperature‑measuring sensors in order to be able to detect a temperature at various points, in particular of the workpiece or test workpiece. A temperature distribution on a workpiece or test workpiece can be advantageously detected and directly adjusted thereby within the preheating unit.

The temperature sensors can be particularly preferably designed as thermocouples, in particular of type K, which are fastened to the workpiece or test workpiece in order to measure the temperature there, in particular directly at the solder joints. In particular, these elements have a sensor-type design and preferably usually is formed of a nickel‑chromium/nickel-aluminum compound and are designed for the temperature range of preferably -200°C to 1260°C. Preferably, the temperature-measuring unit comprises at least two or four or six or even more thermocouples. Advantageously, the thermocouples are particularly robust and cost-effective. Moreover, a temperature of the workpiece or test workpiece can be detected directly by the thermocouples.

The distance-measuring unit can comprise at least one laser sensor for distance measurement. Advantageously, the laser sensor has a high measurement resolution and a high repeat accuracy, so that it is particularly suitable for distance measurement. Advantageously, an optimal distance of the workpiece-carrier unit and thus a workpiece from the soldering nozzle or nozzles of the selective soldering installation can be set in this way.

The distance-measuring unit can comprise at least one support unit with at least one support body having a defined thickness and movable along a height direction. The support body preferably rests on the soldering nozzle for distance measurement. Advantageously, the laser sensor can also be arranged on a side opposite the soldering nozzle in order to measure the distance. Advantageously, the support body can also rest on a plurality of soldering nozzles, so that a distance to a plurality of soldering nozzles can be determined.

The support unit can comprise at least one spring element for preloading the support body against the soldering nozzle. Advantageously, the support body is preloaded by the spring element against one or more soldering nozzles, so that a precise measurement of the distance between the supporting surface of the workpiece-carrier unit and the soldering nozzle is possible.

The wave-height-measuring unit can have at least one measuring point and preferably a plurality of measuring points for measuring the wave height of the solder of one or more soldering nozzles. The wave height of different soldering nozzles can be advantageously calibrated thereby at the same time.

The wave height of a soldering nozzle can be measured by means of contact‑measuring sensors. In particular, at least two or four or more contact-measuring sensors are included, which are attached to the calibrating tool in such a way that they contact the solder wave at outer edges, and in particular in the corners, of the soldering nozzle. Advantageously, a wave height of a soldering nozzle can be precisely measured and calibrated thereby.

At least one evaluation unit for evaluating a measurement signal from the temperature‑measuring unit, a measurement signal from the distance-measuring unit, and/or a measurement signal from the wave-height-measuring unit can be expediently included. Advantageously, the measurement results can be evaluated directly in the calibrating tool. The evaluation unit is advantageously designed as a microprocessor and in particular as an Arduino microprocessor. It is advantageous further that the measurement signals from all measuring units can be evaluated by an Arduino microprocessor. It is particularly advantageous to compare a measured value with a setpoint within the evaluation unit.

The calibrating tool can comprise at least one display unit for displaying whether a setpoint for the temperature, the distance, and/or the wave height is calibrated and corresponds to the respective setpoint. Particularly advantageously, an evaluated measured value can be displayed directly by the display unit and interpreted by the user. In particular, the display unit comprises various LEDs and, in particular, at least one LED per sensor. Preferably, for example, a color of the LEDs can be used to indicate whether a measured value corresponds to a setpoint or not. Advantageously, the user who calibrates the parameters of the selective soldering installation can receive direct feedback on the current setting and a change to a parameter in this way.

At least one housing unit can be included at least for receiving the evaluation unit and/or the display unit. Advantageously, the housing unit enables mechanical and, in particular, thermal protection for the evaluation unit and/or the display unit. The housing unit can be arranged particularly advantageously on or at the workpiece-carrier unit.

At least two workpieces, each with a measuring unit, can be received in the workpiece-carrier unit. Preferably, the measuring units makes measurements on the respective workpiece in the workpiece-carrier unit. Prefabricated calibrating tools with measuring units, for example, can be advantageously inserted into the tool holders. In particular, two or more parameters can be measured and evaluated simultaneously in one process step with very little effort, such as, for example, the temperature and the distance or the temperature and the wave height or the distance and the wave height. A plurality of parameters can be calibrated advantageously thereby in relation to each other and their interactions can be taken into account. For example, an effect of the temperature and/or the distance of a circuit board on the wave height can be evaluated or vice versa. By taking into account the mutual influence of the parameters, the parameters can be adjusted relative to each other. For example, an influence of cooling of the temperature after preheating on the other parameters can be taken into account in the process. This is particularly important for mini-wave soldering especially, because the area of the soldering nozzles is kept as small as possible here, so that even smaller or very small temperature changes, especially in connection with the distance and/or wave height, can influence the wetting of the surface of the workpiece with solder.

At least two measuring units can be present, which are received on one workpiece. Particularly preferably, three or also more measuring units, and in particular all available measuring units, are received on one workpiece. Preferably, the measuring units make measurements on the one workpiece. In particular, the parameters can be measured and calibrated thereby on a workpiece, preferably at the same time during a pass through the selective soldering installation. This is particularly relevant for mini-wave soldering, because the workpieces should be brought into contact with the solder only in a small area and, in particular, precisely at the soldering points. In this way, interactions between the individual parameters on a workpiece, such as a distance, a temperature, and in particular a local temperature at the respective soldering point, and a wave height, can be taken into account during calibration. The calibration of soldering process parameters can thus be optimized even further, so that an optimal work result is achieved with a minimum use of resources.

The selective soldering installation of the invention comprises at least one preheating unit for preheating a workpiece, such as a circuit board, before a soldering process and/or at least one soldering unit with at least one soldering nozzle for selectively producing a solder connection on a circuit board and at least one previously described calibrating tool. Refinements and advantages of the selective soldering installation of the invention emerge from the entire application.

The method of the invention for calibrating the preheating unit and/or the soldering unit of a previously described selective soldering installation using a previously described calibrating tool comprises at least the following method steps: measuring a preheating temperature by means of the temperature-measuring unit and adjusting a heating output of the preheating unit, in particular until a setpoint is reached; and/or measuring the distance of the workpiece receiving surface of the workpiece-carrier unit by means of the distance-measuring unit and adjusting the distance of the workpiece receiving surface from at least one soldering nozzle, in particular until a setpoint is reached; and/or measuring the wave height of at least one soldering nozzle and adjusting at least one wave height at the soldering nozzle on the soldering unit, in particular until a setpoint is reached.

The method of the invention as well has many advantages. A significant advantage of the method is that a calibration of the selective soldering installation can take place much more rapidly by using the calibrating tool than previously known in the state of the art, so that downtimes and personnel costs are reduced and the economic efficiency of the selective soldering installation is improved. Refinements and advantages of the method of the invention emerge from the entire general description and from the description of the examples.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a purely schematic process diagram of a selective soldering installation of the invention;

FIG. 2 is a purely schematic view of a calibrating tool of the invention with a temperature-measuring unit;

FIG. 3 is a purely schematic view of a calibrating tool of the invention with a distance‑measuring unit; and

FIG. 4 is a purely schematic view of a calibrating tool of the invention with a wave‑height-measuring unit

FIG. 5 is a purely schematic view of a further example of a calibrating tool of the invention with a workpiece-carrier unit with multiple workpieces with measuring units; and

FIG. 6 is a purely schematic view of further examplesof calibrating tools of the invention with multiple workpieces, where two or more measuring units are received on one workpiece.

### DETAILED DESCRIPTION

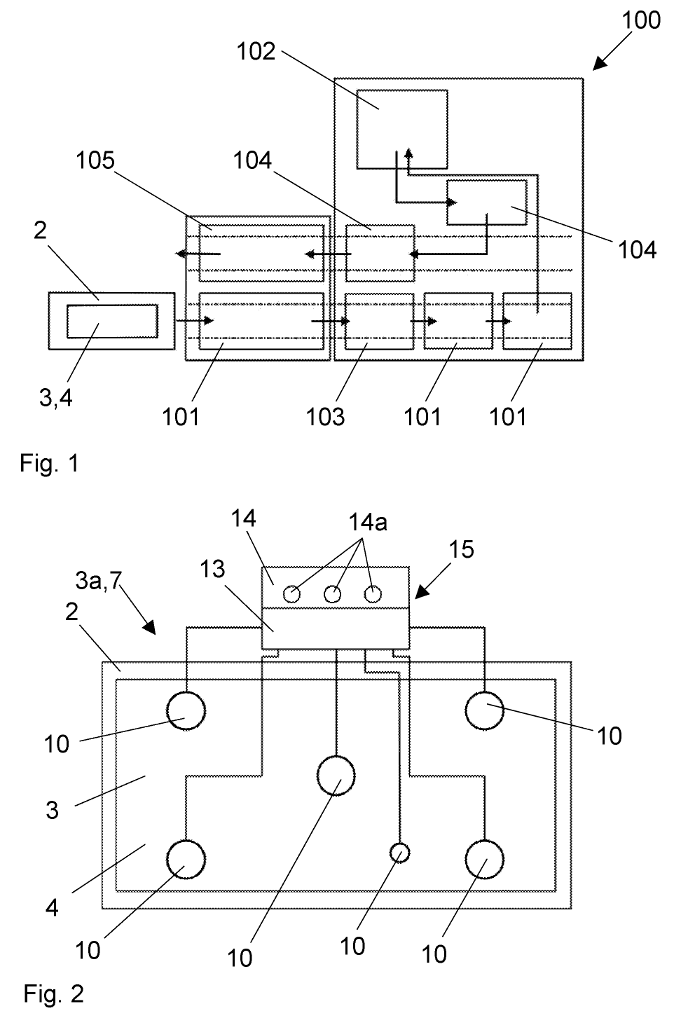

FIG. 1 shows a purely schematic process diagram of a selective soldering installation 100 of the invention. For selective soldering of components on workpieces 3, such as a circuit board 4, the workpiece is placed in a workpiece-carrier unit 2.

Workpiece 3 is then heated in a preheating unit 101. Pyrometers 101 are used here for this purpose. Flux is then applied by a flux application unit 103. Workpiece 3 is then gradually heated to the temperature required for soldering in two additional preheating units 101 using pyrometers 101.

Components are selectively soldered into workpiece 3 in soldering unit 102. A two-stage cleaning of the solder joints by brush units 104 then takes place before the finished soldered workpiece 3 is cooled in a controlled manner in a cooling unit 105.

FIG. 2 shows a purely schematic view of a calibrating tool 1 of the invention with a temperature-measuring unit 7 as measuring unit 3a. Temperature-measuring unit 7 here comprises a workpiece 3, which is designed as a test workpiece 3 in the form of a circuit board 4 and is received in the workpiece-carrier unit 2. Six temperature-measuring sensors 10 in the form of type K thermocouples are placed here on test workpiece 3. Temperature-measuring sensors 10 are arranged distributed across test workpiece 3 and connected to an evaluation unit 13. Evaluation unit 13 detects the measurement signals from all temperature-measuring sensors 10 and evaluates them. For this purpose, evaluation unit 13 comprises an analog-to-digital converter. Evaluation unit 13 is designed here as an Arduino microprocessor. Evaluation unit 13 also carries out a setpoint comparison between the measured temperature and a specified setpoint temperature for each temperature-measuring sensor. The result of the setpoint comparison is transmitted to a display unit 14. The result of the setpoint comparison is displayed here via LEDs 14a. In this case, one LED is assigned to each temperature sensor. Depending on the color in which the LED lights up, a user receives feedback as to whether a setpoint for the temperature has been reached, is below it, or has already been exceeded. Accordingly, they can adjust a heating output of a pyrometer 101 of a preheating unit 101 and thus directly calibrate preheating unit 101 of selective soldering installation 100 in situ.

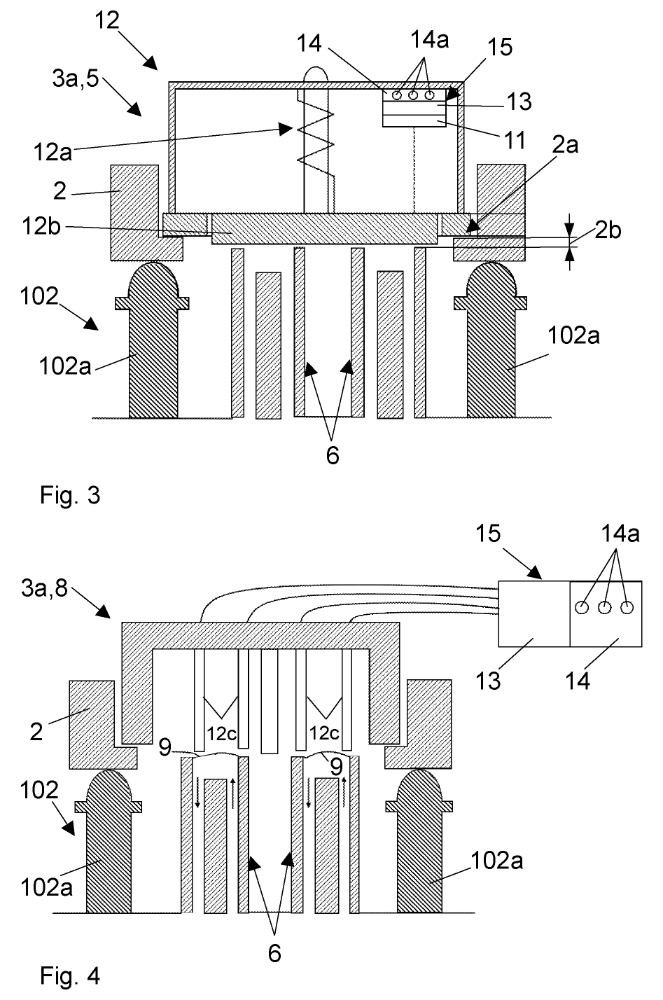

FIG. 3 shows a purely schematic view of a calibrating tool 1 of the invention with a distance-measuring unit 5 as measuring unit 3a. Distance-measuring unit 5 is received here on a workpiece 3 in workpiece-carrier unit 2. Distance-measuring unit5 comprises a support unit 12. Support unit 12 here comprises a contact body 12b that can move in a height direction transverse to a plane of a supporting surface 2a of workpiece-carrier unit 2, which in this case, preloaded by a spring element 12a, rests on soldering nozzles 6 of soldering unit 102. Distance-measuring unit 5 rests on supporting surface 2a of workpiece-carrier unit 2. Support body 12b has a defined thickness here, so that a distance 2b between supporting surface 2a and soldering nozzles 6 can be determined by means of a measurement by a laser sensor 11, which is arranged at a defined height. The optimal distance 2b here is, e.g., between 0.5 mm and 1 mm depending on the selective soldering installation 100. Evaluation unit 13 evaluates the measurement signal from laser sensor 11 and compares it with the setpoint. The result of the comparison is displayed using LEDs 14a on display unit 14. The distance 2b can be adjusted by screwing in or out adjusting elements 102a, which are designed here as threaded rods with cap nuts 102a, in order to calibrate the distance 2b directly.

FIG. 4 shows a purely schematic view of a calibrating tool 1 of the invention with a wave‑height-measuring unit 8 as measuring unit 3a for measuring wave height 9. Wave‑height-measuring unit 8 is received here on a workpiece 3 in workpiece-carrier unit 2. There is a measuring point for each soldering nozzle 6. A measuring point has multiple contact-measuring sensors 12c, which are arranged at an optimal distance at the corners of soldering nozzle 6 with a rectangular cross section. A solder flow in soldering nozzles 6 can be adjusted In this way, so that an optimal wave height 9 is available for the soldering process at each soldering nozzle 6. In this regard, the measurement signals from contact-measuring sensors 12c are evaluated by evaluation unit 13 and the result is also shown to the user here by display unit 14 via LEDs 14a, so that the user can calibrate wave height 9 directly.

Advantageously, calibrating tool 1 enables efficient and rapid calibration of the individual parameters of a selective soldering installation 100. During use, a user receives direct feedback on the current setting of the parameters and can adjust them directly, i.e., in situ, in order to optimally calibrate the parameters of selective soldering installation 100. This minimizes the influence of the user's experience, because the user receives direct feedback about a change in the parameter setting. Advantageously, the downtimes of a selective soldering installation 101 can thus be at least considerably reduced, so that the economic efficiency of selective soldering installation 101 increases.

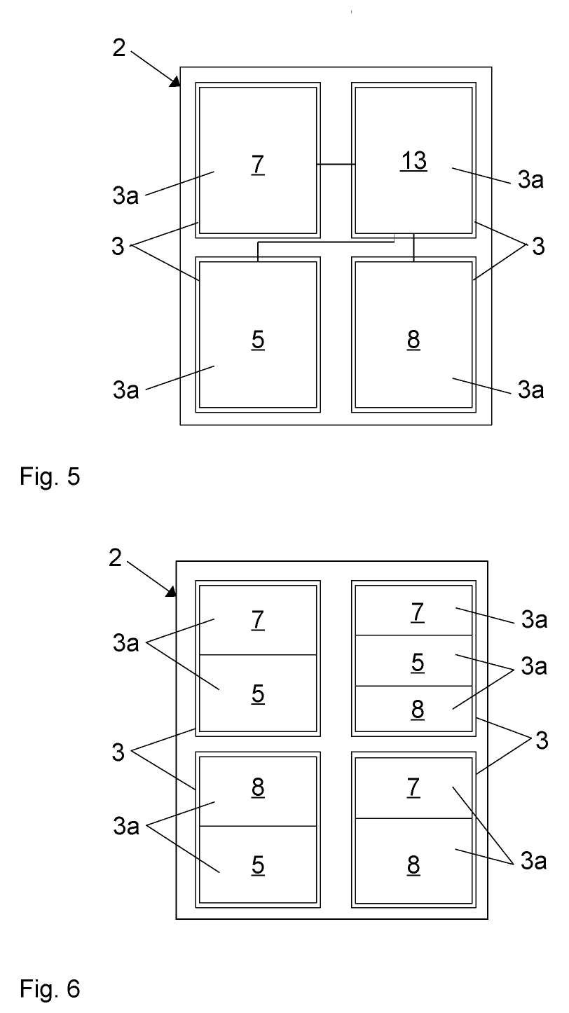

FIG. 5 shows a purely schematic view of an example of a calibrating tool 1 of the invention with a workpiece-carrier unit 2 for receiving multiple workpieces 3. There are three workpieces 3 with measuring units 3a, which measure the parameters in different tool holders simultaneously. A workpiece 3 with a distance-measuring unit 5, a temperature-measuring unit 7, and a wave-height-measuring unit 8 is shown in workpiece-carrier unit 2. The evaluation is carried out here in a separate evaluation unit 13, to which measuring units 3a are connected. Measuring units 3a can be used to measure and determine all parameters, i.e., the distance 2b, the temperature, and wave height 9 in the machining process within selective soldering installation 100. Advantageously, reciprocal influences of parameters can also be taken into account thereby during calibration.

FIG. 6 shows a purely schematic view of examples of calibrating tools 1 of the invention. Multiple workpieces 3 are present in workpiece-carrier unit 2, whereby two or more measuring units 3a are received on one workpiece 3. In an example, three measuring units 3a are received in a workpiece 3. Measuring units 3a make measurements on the respective workpiece 3 on which they are received. Further, the evaluation is carried out separately on each workpiece 3. Advantageously, the parameters of selective soldering installation 100 can be adjusted thereby to each other on a workpiece 3 using a real run through the process of selective soldering installation 100. Particularly advantageously, it can be checked thereby whether the required local temperature at a soldering point after preheating is also set in conjunction with wave height 9 and the distance 2b in such a way that an even better soldering result is achieved, wherein the use of solder and the size of soldering nozzles 6 can be optimized for mini-wave soldering. Further, a required installation space is particularly small if, as here, all measuring units 3a are received on one workpiece.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A calibrating tool to calibrate a selective soldering installation, the calibrating tool comprising:
a workpiece-carrier unit for receiving at least one or more workpieces;
at least one workpiece or a circuit board; and
at least one measuring unit designed as:
at least one distance-measuring unit adapted to be received within the workpiece-carrier unit and provided to calibrate a distance of a supporting surface of the workpiece-carrier unit from at least one soldering nozzle of a soldering unit; or
at least one temperature-measuring unit adapted to be received within the workpiece-carrier unit and provided to calibrate at least one heating output of a preheating unit; or
at least one wave-height-measuring unit adapted to be received within the workpiece-carrier unit and provided to calibrate a wave height of at least one soldering nozzle of a soldering unit.

2. The calibrating tool according to claim 1, wherein the temperature‑measuring unit comprises at least two temperature‑measuring sensors in order to detect a temperature at various points within the workpiece-receiving unit.

3. The calibrating tool according to claim 2, wherein the temperature sensors are designed at least in part as thermocouples of type K.

4. The calibrating tool according to claim 1, wherein the distance-measuring unit comprises at least one laser sensor for distance measurement.

5. The calibrating tool according to claim 1, wherein the distance-measuring unit comprises at least one support unit with at least one support body movable along a height direction, and wherein the support body, which has a defined thickness, rests on the soldering nozzle for distance measurement.

6. The calibrating tool according to claim 1, wherein the support unit comprises at least one spring element to preload the support body against the soldering nozzle.

7. The calibrating tool according to claim 1, wherein the wave-height-measuring unit has at least two measuring points to measure a wave height of the solder of at least two of soldering nozzles.

8. The calibrating tool according to claim 1, wherein the wave height of a soldering nozzle is measured via four contact-measuring sensors.

9. The calibrating tool according to claim 1, further comprising at least one evaluation unit to evaluate a measurement signal from the temperature-measuring unit, a measurement signal from the distance-measuring unit, and/or a measurement signal from the wave-height-measuring unit.

10. The calibrating tool according to claim 1, further comprising at least one display to display whether a setpoint for the temperature, the distance, and/or the wave height has been reached.

11. The calibrating tool according to claim 9, further comprising at least one housing to receive the evaluation unit and/or the display unit.

12. The calibrating tool according to claim 1, wherein at least two workpieces, each with a measuring unit, are received in the workpiece-carrier unit, which make measurements on different workpieces, or wherein at least two measuring units are received on one workpiece, which make measurements on the one workpiece.

13. The calibrating tool according to claim 1, wherein the at least one workpiece is a circuit board.

14. A selective soldering installation comprising:
at least one preheating unit to preheat a workpiece or a circuit board before a soldering process; and/or
at least one soldering unit with at least one soldering nozzle to selectively produce a solder connection on a circuit board; and
the at least one calibrating tool according to claim 1.

15. A method to calibrate a preheating unit and/or a soldering unit of the selective soldering installation according to claim 14 via the calibrating tool, the method comprising:
measuring a preheating temperature via the temperature‑measuring unit, and adjusting a heating output of the preheating unit; and/or
measuring a distance of the workpiece-receiving surface of the workpiece-carrier unit via the distance-measuring unit and adjusting the distance of the workpiece-receiving surface from at least one soldering nozzle; and/or
measuring the wave height of at least one soldering nozzle and adjusting at least one wave height at the soldering nozzle on the soldering unit.
